(19) United States
(12) Patent Application Publication
(10) Pub. No.: US 2016/0043205 A1
(43) Pub. Date: Feb. 11, 2016

(54) SEMICONDUCTOR DEVICE

(71) Applicant: Kabushiki Kaisha Toshiba, Tokyo (JP)

(72) Inventor: Shuji Kamata, Nonoichi Ishikawa (JP)

(21) Appl. No.: 14/644,011

(22) Filed: Mar. 10, 2015

(30) Foreign Application Priority Data
Aug. 5, 2014 (JP) 2014-159590

(51) Int. Cl. H01L 29/739; H01L 29/10

(52) U.S. Cl. CPC H01L 29/7395; H01L 29/1095

(57) ABSTRACT

A semiconductor device according to embodiments includes: a semiconductor substrate including; a first semiconductor layer of a first conductivity type; a second semiconductor layer of a second conductivity type above the first semiconductor layer; a third semiconductor layer above the second semiconductor layer; a plurality of gate layers arranged inside the semiconductor substrate, the gate layers extending in a first direction and being arranged in line in a second direction orthogonal to the first direction; a plurality of first semiconductor regions of the second conductivity type arranged on the third semiconductor layer between a first gate layer and a second gate layer of the gate layers, the first and second gate layers being adjacent to each other; a gate insulating film having a larger film thickness at a region excluding the first semiconductor regions than at the first semiconductor regions; an emitter electrode; and a collector.

### CROSS-REFERENCE TO RELATED APPLICATION

This application is based upon and claims the benefit of priority from Japanese Patent Application No. 2014-159590, filed on Aug. 5, 2014, the entire contents of which are incorporated herein by reference.

### FIELD

Embodiments described herein relate generally to semiconductor devices.

### BACKGROUND

one example of power semiconductor devices is insulated gate bipolar transistors (IGBTs). In order to reduce on-state voltage, trench gate IGBTs adopting trench gates are used.

With trench gate IGBTs, electron injection from an emitter can be boosted and on-state voltage can be lowered by decreasing trench gate intervals through scaling-down of a device. However, scaling-down of a device may lead to increase in gate capacitance and deceleration of switching speed.

### BRIEF DESCRIPTION OF THE DRAWINGS

FIGS. 1A and 1B are schematic cross-sectional views of a semiconductor device according to a first embodiment.

FIG. 2 is a schematic plan view of the semiconductor device according to the first embodiment.

FIG. 3 is a schematic diagram of the semiconductor device in a manufacturing process of a method of manufacturing the semiconductor device according to the first embodiment.

FIGS. 4A and 4B are schematic diagrams of the semiconductor device in a manufacturing process of the semiconductor device manufacturing method according to the first embodiment.

FIG. 5 is a schematic diagram of the semiconductor device in a manufacturing process of the semiconductor device manufacturing method according to the first embodiment.

FIGS. 6A and 6B are schematic diagrams of the semiconductor device in a manufacturing process of the semiconductor device manufacturing method according to the first embodiment.

FIG. 7 is a schematic diagram of the semiconductor device in a manufacturing process of the semiconductor device manufacturing method according to the first embodiment.

FIG. 8A and 8B are schematic diagrams of the semiconductor device in a manufacturing process of the semiconductor device manufacturing method according to the first embodiment.

FIG. 9 is a schematic diagram of the semiconductor device in a manufacturing process of the semiconductor device manufacturing method according to the first embodiment.

FIG. 10A and 10B are schematic diagrams of the semiconductor device in a manufacturing process of the semiconductor device manufacturing method according to the first embodiment.

FIG. 11 is a schematic plan view of a semiconductor device according to a second embodiment.

FIG. 12 is a schematic plan view of a semiconductor device according to a third embodiment.

FIG. 13 is a schematic plan view of the semiconductor device in a manufacturing process of a method of manufacturing the semiconductor device according to the third embodiment.

FIG. 14 is a schematic plan view of the semiconductor device in a manufacturing process of the semiconductor device manufacturing method according to the third embodiment.

FIGS. 15A and 15B are schematic cross-sectional views of a semiconductor device according to a fourth embodiment.

FIG. 16 is a schematic plan view of the semiconductor device according to the fourth embodiment.

### DETAILED DESCRIPTION

A semiconductor device according to embodiments includes: a semiconductor substrate having a first surface and a second surface opposite the first surface; a first semiconductor layer of a first conductivity type provided in the semiconductor substrate, the first semiconductor layer provided at a first surface side of the semiconductor substrate; a second semiconductor layer of a second conductivity type provided in the semiconductor substrate, the second semiconductor layer provided between the first semiconductor layer and the second surface; a third semiconductor layer of the first conductivity type provided in the semiconductor substrate, the third semiconductor layer provided between the second semiconductor layer and the second surface; a plurality of gate layers provided inside the semiconductor substrate, the gate layers extending in a first direction and being arranged in line in a second direction orthogonal to the first direction, a distance between the gate layers and the first surface is smaller than a distance between the third semiconductor layer and the first surface; a plurality of first semiconductor regions of the second conductivity type provided in the third semiconductor layer between a first gate layer and a second gate layer of the gate layers, the first and second gate layers being adjacent to each other; a gate insulating film provided between the first gate layer and each of the second semiconductor layer, the third semiconductor layer, and the first semiconductor regions, a thickness of the gate insulating film between the first gate layer and a region excluding the first semiconductor regions being larger than a thickness of the gate insulating film between the first gate layer and the first semiconductor regions; an emitter electrode electrically connectable with the first semiconductor regions; and a collector electrode electrically connectable with the first semiconductor layer.

Embodiments of the present invention are described below with reference to the drawings. It is to be noted that in the following description, the same members and portions are assigned the same reference numerals, and description is not given where appropriate of the members and portions described once. It is to be noted that in the following embodiments, description is given by way of an example of a case in which the first conductivity type is p-type and the second conductivity type is n-type.

Further, the indications of n⁺-type, n-type, and n⁻-type herein mean that n-type impurity concentration is lower in this order. Likewise, the indications of p⁺-type, p-type, and p⁻-type mean that p-type impurity concentration is lower in this order.

The n-type impurities are, for example, phosphorus (P) or arsenic (As). Further, the p-type impurities are, for example, boron (B).

### FIRST EMBODIMENT

A semiconductor device according to the first embodiment includes: a semiconductor substrate having a first surface and a second surface opposite the first surface; a first semiconductor layer of the first conductivity type provided at a side of the semiconductor substrate facing toward the first surface; a second semiconductor layer of the second conductivity type provided at aside of the first semiconductor layer facing toward the second surface; a third semiconductor layer of the first conductivity type provided at a side of the second semiconductor layer facing toward the second surface; a plurality of gate layers arranged inside the semiconductor substrate, the gate layers extending in a first direction and being arranged in line in a second direction orthogonal to the first direction, the gate layers having ends on a side facing toward the first surface closer to the first surface than the third semiconductor layer; a plurality of first semiconductor regions of the second conductivity type arranged on the third semiconductor layer between a first gate layer and a second gate layer of the gate layers, the first and second gate layers being adjacent to each other; a second semiconductor region of the first conductivity type provided between the first semiconductor regions adjacent to each other in the first direction; a gate insulating film provided between the first gate layer and each of the second semiconductor layer, the third semiconductor layer, the first semiconductor regions, and the second semiconductor region, the gate insulating film having a larger film thickness with the second semiconductor region than with the first semiconductor regions; an emitter electrode electrically connectable with the first and second semiconductor regions; and a collector electrode electrically connectable with the first semiconductor layer. Further, a semiconductor device according to the embodiment includes: a semiconductor substrate having a first surface and a second surface opposite the first surface; a gate layer disposed inside the semiconductor substrate; a channel region disposed in the semiconductor substrate; a gate insulating film disposed between the gate layer and the semiconductor substrate, the gate insulating film having a larger film thickness with a region excluding the channel region than with the channel region; an emitter electrode disposed on a side of the semiconductor substrate facing toward the second surface; and a collector electrode disposed on a side of the semiconductor substrate facing toward the first surface.

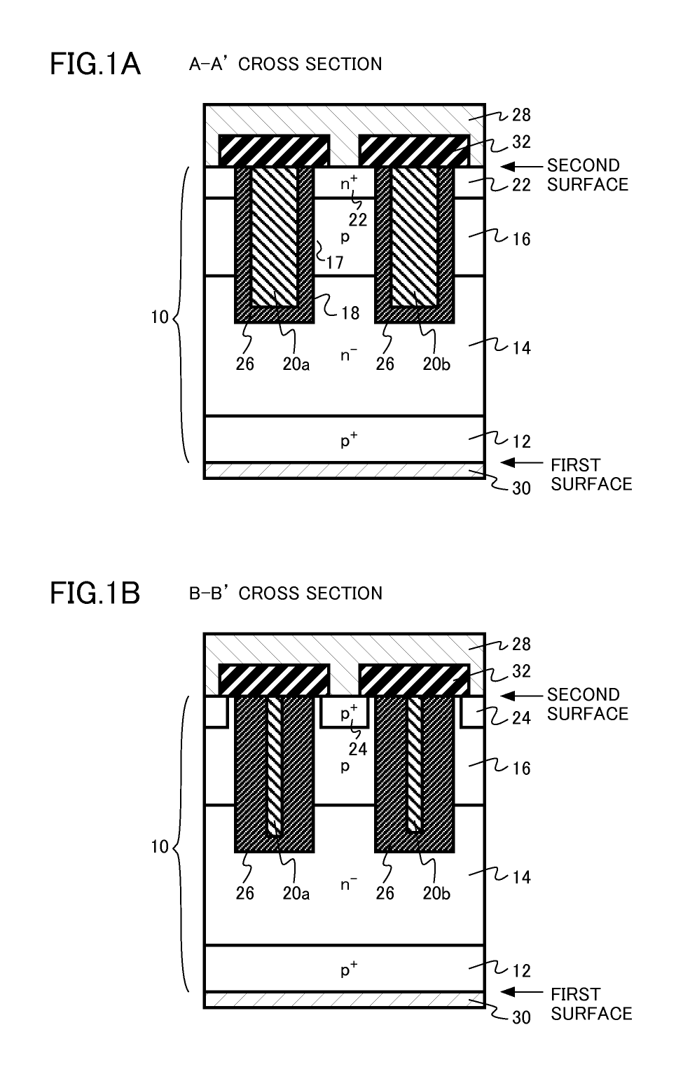

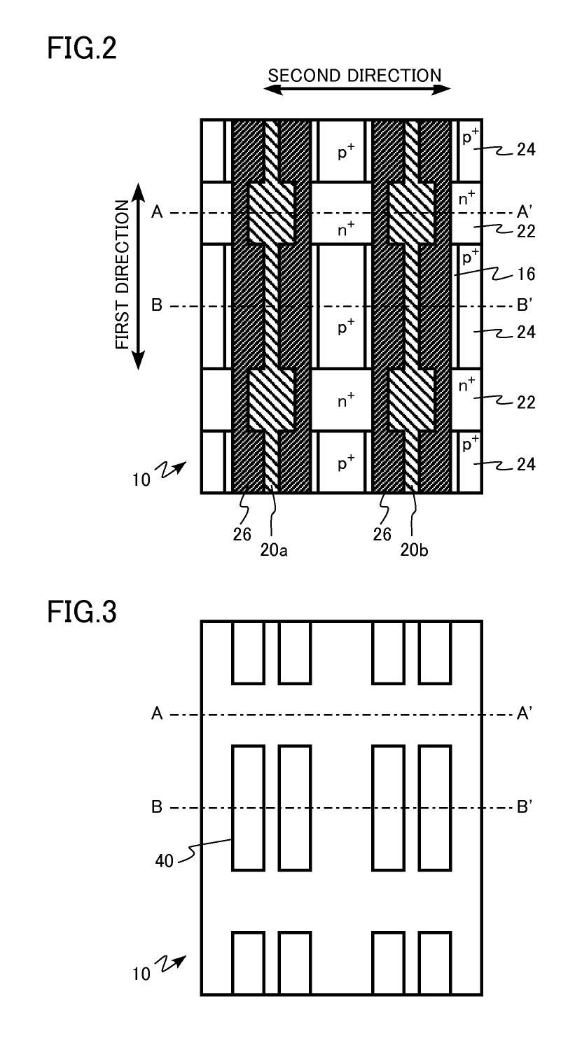

FIGS. 1A and 1B are schematic cross-sectional views of a semiconductor device according to the first embodiment. FIG. 2 is a schematic plan view of the semiconductor device according to the first embodiment. FIG. 1A depicts a cross section taken along line A-A′ in FIG. 2. FIG. 1B depicts a cross section taken along line B-B′ in FIG. 2. It is to be noted that FIG. 2 is a plan view of a state in which portions such as interlayer dielectrics and an emitter electrode are removed from a semiconductor substrate.

The semiconductor device according to the present embodiment is a trench IGBT that has an emitter electrode and a collector electrode arranged with a semiconductor substrate interposed therebetween, and that gate electrodes are buried in trenches in the semiconductor substrate.

The IGBT of the present embodiment includes, as depicted in FIGS. 1A and 1B, a semiconductor substrate 10 having a first surface and a second surface opposite the first surface. The semiconductor substrate 10 is, for example, monocrystalline silicon.

A p⁺-type collector layer (first semiconductor layer) 12 is disposed on the first surface side of the semiconductor substrate 10. An n⁻-type drift layer (second semiconductor layer) 14 is disposed on the second surface side of the p⁺-type collector layer 12. Moreover, a p-type base layer (third semiconductor layer) 16 is disposed on the second surface side of the drift layer 14.

A plurality of gate layers 20a and 20b is arranged inside the semiconductor substrate 10. The plurality of gate layers 20a and 20b is buried in trenches 18 formed in the semiconductor substrate 10.

The gate layers 20a and 20b extend in a first direction and are lined in a second direction orthogonal to the first direction. The first direction and the second direction are parallel to the first surface.

The gate layers 20a and 20b are, for example, polycrystalline silicon doped with n-type impurities. It is to be noted that although two gate layers are exemplarily provided in FIGS. 1A, 1B, and 2, the gate layers maybe provided by three or more.

The trenches 18 extend deeper than the boundary between the drift layer 14 and the base layer 16. The gate layers 20a and 20b have ends thereof on the first surface side closer to the first surface than the boundary between the drift layer 14 and the base layer 16. The base layer 16 facing the gate layers 20a and 20b functions as a channel region of the IGBT.

A plurality of n⁺-type emitter regions (first semiconductor regions) 22 are arranged on the surface of the base layer 16 between the first gate layer 20a and the second gate layer 20b. Further, p⁺-type base contact regions (second semiconductor regions) 24 are each arranged on the surface of the base layer 16 between the emitter regions 22 adjacent to each other in the first direction. The base contact regions 24 have a function of boosting discharge of holes when the IGBT is turned off.

Gate insulating films 26 are arranged between the first and second gate layers 20a and 20b and the drift layer 14, the base layer 16, the emitter regions 22, as well as the base contact regions 24. The gate insulating films 26 are arranged on the inner surfaces of the trenches 18. The gate insulating films 26 are, for example, silicon oxide films. The silicon oxide films are, for example, thermal oxide films of silicon. The gate layers 20a and 20b are arranged over the gate insulating films 26.

It is to be noted here that the regions, in contact with the gate insulating films 26, of the base layer 16 between the emitter regions 22 and the drift layer 14 make channel regions 17. Inversion layers are formed on the channel regions 17 and carriers flow in the channel regions 17 in the on-state of the IGBT.

The film thickness of the gate insulating films 26 between the first and second gate layers 20a and 20b and regions excluding the n⁺-type emitter regions (first semiconductor regions) 22 is larger than the film thickness of the gate insulating films 26 between the first and second gate layers 20a and 20b and the n⁺-type emitter regions (first semiconductor regions) 22. Further, the film thickness of the gate insulating films 26 between the first and second gate layers 20a and 20b and regions excluding the channel regions 17 is larger than the film thickness of the gate insulating films 26 between the first and second gate layers 20a and 20b and the channel regions 17.

The film thickness of the gate insulating films 26 between the first and second gate layers 20a and 20b and the base contact regions 24 is larger than the film thickness of the gate insulating films 26 between the first and second gate layers 20a and 20b and the emitter regions 22. Further, as depicted in FIG. 1A and 1B, the film thickness of the gate insulating films 26 between the first and second gate layers 20a and 20b and the drift layer 14 as well as the base layer 16 is desirably larger on the first surface side of the base contact regions 24 than on the first surface side of the emitter regions 22. The regions of the gate insulating films 26 with a larger film thickness is desirably at a deeper level than the boundary between the drift layer 14 and the base layer 16.

Further, the IGBT of the present embodiment includes an emitter electrode 28 electrically connected with the emitter regions 22 and the base contact regions 24. Further, the IGBT includes a collector electrode 30 electrically connected with the collector layer 12. The emitter electrode 28 and the collector electrode 30 are, for example, a metal containing aluminum.

Interlayer dielectrics 32 are arranged between the emitter electrode 28 and the gate layers 20a and 20b. The interlayer dielectrics 32 are, for example, silicon oxide films.

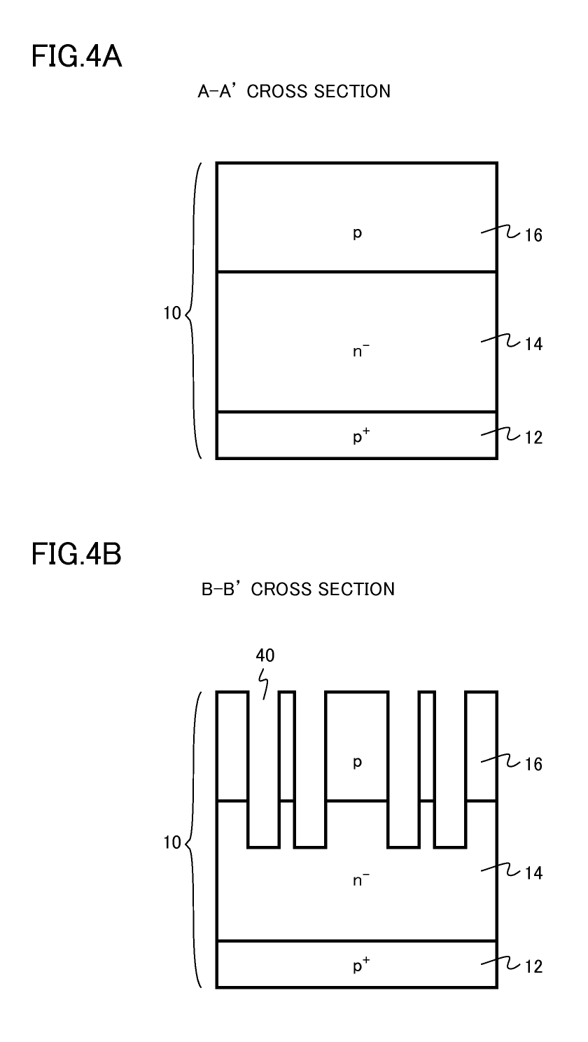

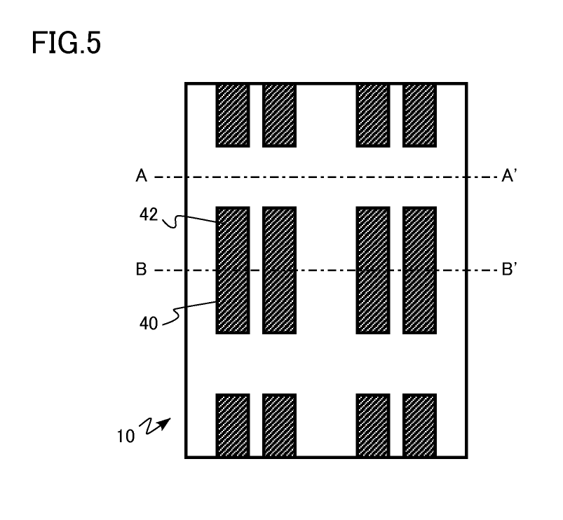

Next, description is given of an exemplary method of manufacturing the semiconductor device according to the present embodiment. FIGS. 3, 4A, 4B, 5, 6A, 6B, 7, 8A, 8B, 9, and 10 are schematic diagrams of the semiconductor device in manufacturing processes of the semiconductor device manufacturing method according to the present embodiment. FIGS. 3, 5, 7, and 9 are plan views, and FIGS. 4A, 4B, 6A, 6B, 8A, 8B, and 10 are cross-sectional views.

First, a semiconductor substrate 10 is prepared which has an n⁻-type drift layer 14 and a p-type base layer 16 formed on an n⁺-type substrate (collector layer) 12. The drift layer 14 is, for example, formed on the substrate (collector layer) 12 by an epitaxial growth method. Further, the base layer 16 is formed, for example, by ion implantation of p-type impurities into the drift layer 14 and thermally diffuses the impurities.

Next, first trenches 40 are formed from the surface of the semiconductor substrate 10 (FIGS. 3, 4A, and 4B.) The first trenches 40 are desirably formed deeper than the boundary between the base layer 16 and the drift layer 14.

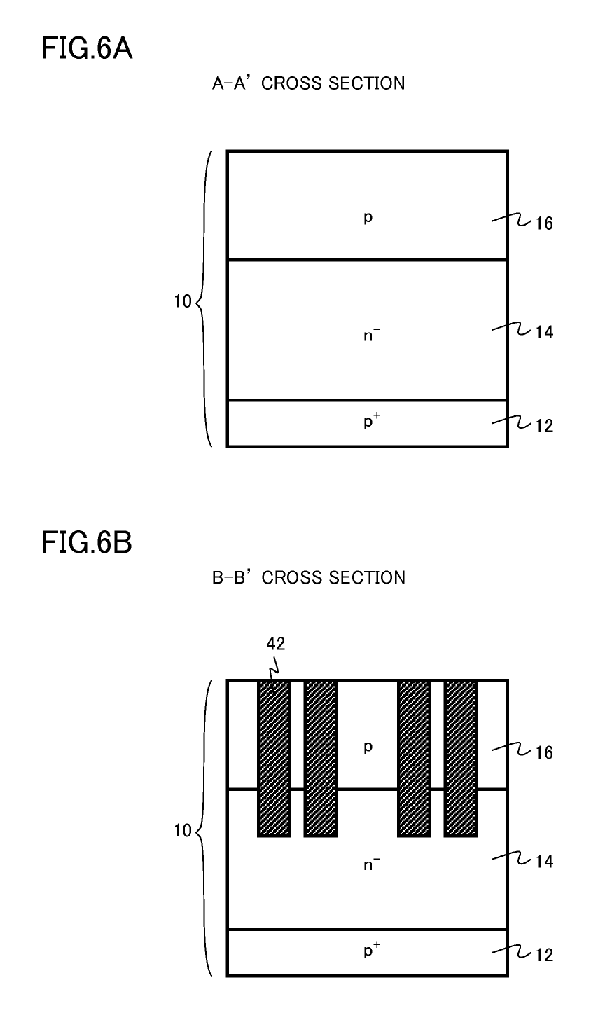

Next, first insulating films 42 are buried in the first trenches 40 (FIGS. 5, 6A, and 6B.) The first insulating films 42 are, for example, silicon oxide films formed by chemical vapor deposition (CVD.)

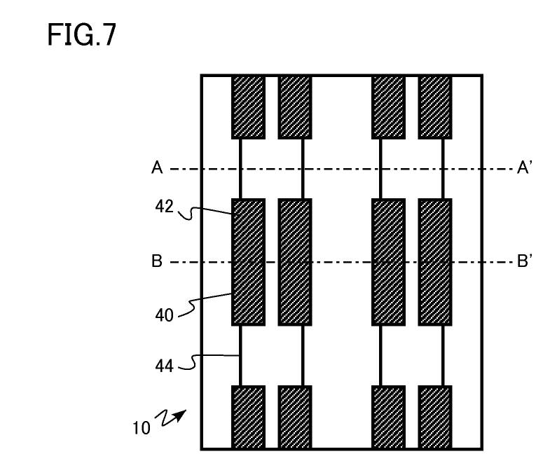

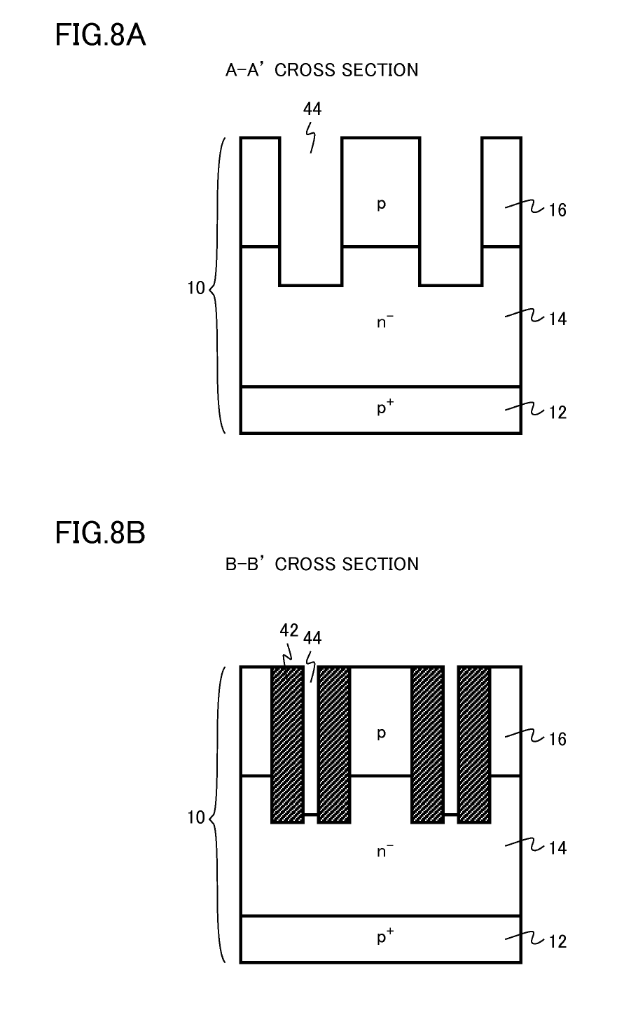

Next, second trenches 44 are formed from the surface of the semiconductor substrate 10 (FIGS. 7, 8A, and 8B.) The second trenches 44 are formed over each of the insulating films 42 buried in the first trenches 40. The second trenches 44 are formed deeper than the boundary between the base layer 16 and the drift layer 14.

Next, second insulating films 46 are formed over the inner surfaces of the second trenches 44. The second insulating films 46 are, for example, silicon oxide films. The second insulating films 46 are, for example, thermal oxide films made by thermal oxidation. The second insulating films 46 may be deposited films formed by CVD in place of thermal oxide films.

The second insulating films 46 are formed to have a smaller film thickness than the first insulating films 42. The first insulating films 42 and the second insulating films 46 make the gate insulating films 26.

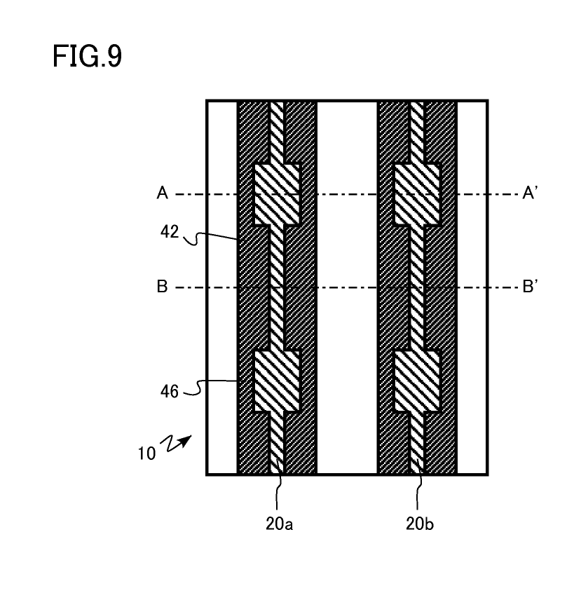

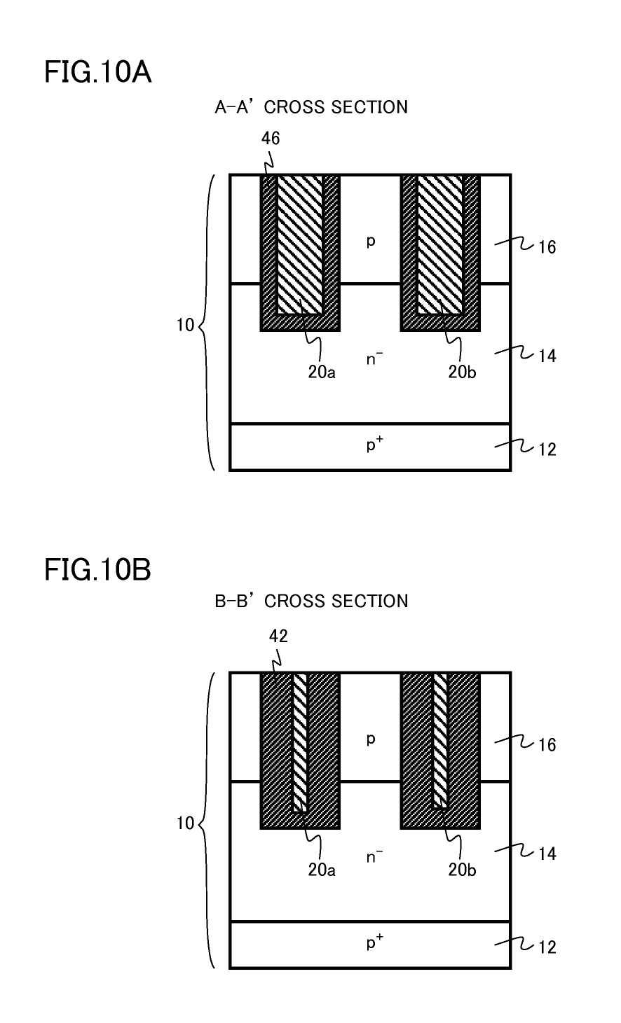

Moreover, a conductive material is formed on the second insulating films 46 such that the second trenches 44 are buried. The conductive material is, for example, polycrystalline silicon doped with n-type impurities. The surface of the conductive material is polished, for example, by chemical mechanical polishing (CMP) to form gate layers 20a and 20b (FIGS. 9, 10A, and 10B.)

After that, emitter regions 22, base contact regions 24, interlayer dielectrics 32, an emitter electrode 28, and a collector electrode 30 are formed by known methods, so as to complete the IGBT depicted in FIGS. 1A, 1B, and 2.

Next, description is given of functions and effects of the semiconductor device according to the present embodiment.

In the IGBT, increase in gate capacitance, which is capacitance between the gate layers and the semiconductor substrate, causes deceleration of switching speed between turn-on and turn-off of the device. Thus, the operating speed of the device may become slow, or the power consumption may increase.

In the IGBT of the present embodiment, the film thickness of the gate insulating films 26 between the first and second gate layers 20a and 20b and the base contact regions 24 is larger than the film thickness of the gate insulating films 26 between the first and second gate layers 20a and 20b and the emitter regions 22. In other words, the gate insulating films 26 have a smaller thickness in the regions where the gate insulating films 26 contribute as gate insulating films of the transistor, while having a larger thickness in the regions where the gate insulating films 26 do not contribute as gate insulating films.

The gate capacitance is reduced by the larger thickness of the gate insulating films 26 in the regions where gate insulating films 26 do not contribute as gate insulating films of the transistor. Hence, deceleration of switching speed of the IGBT is suppressed.

It is to be noted that the gate insulating films 26 in the regions where gate insulating films 26 do not contribute as gate insulating films of the transistor desirably have a larger film thickness over the widest possible area from the viewpoint of reducing gate capacitance. Hence, the film thickness of the gate insulating films 26 between the first and second gate layers 20a and 20b and the drift layer 14 as well as the base layer 16 is desirably larger on the first surface side of the base contact regions 24 than on the first surface side of the emitter regions 22. The regions of the gate insulating films 26 with the larger film thickness is desirably deeper than the boundary between the drift layer 14 and the base layer 16.

### SECOND EMBODIMENT

A semiconductor device according to a second embodiment is the same as that of the first embodiment except that the gate insulating films and the gate layers have different shapes. Hence, details overlapping those of the first embodiment are not described redundantly.

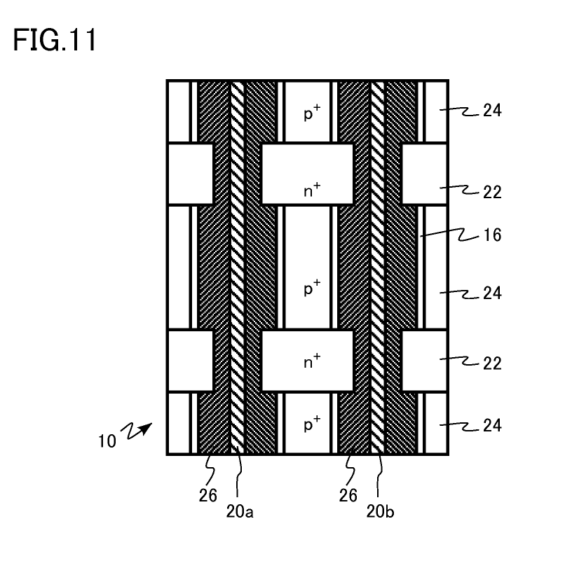

FIG. 11 is a schematic plan view of the semiconductor device according to the second embodiment. The semiconductor device according to the second embodiment has raised and recessed portions on the interfaces between gate insulating films 26 and the semiconductor substrate 10, and the interfaces between gate layers 20a and 20b and the gate insulating films 26 are linear.

In the IGBT of the second embodiment also, gate capacitance is reduced and deceleration of switching speed is suppressed as in the first embodiment.

### THIRD EMBODIMENT

A semiconductor device according to a third embodiment is the same as that of the first embodiment except that regions of a larger film thickness and regions of a smaller film thickness are alternately arranged in the first direction in the gate insulating films located between a first gate layer and a second semiconductor region. Hence, details overlapping those of the first embodiment are not described redundantly.

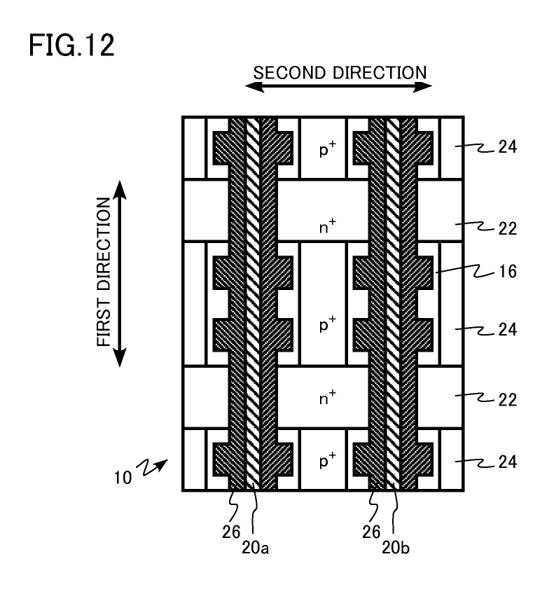

FIG. 12 is a schematic plan view of the semiconductor device according to the third embodiment. The semiconductor device according to the third embodiment has a shape in which gate insulating films 26 between first and second gate layers 20a and 20b and the base contact regions 24 comprise regions of a larger film thickness and regions of a smaller film thickness arranged alternately in the first direction. In other words, the gate insulating films 26 between the first and second gate layers 20a and 20b and the base contact regions 24 have raised and recessed interfaces with the semiconductor substrate 10 along the first direction.

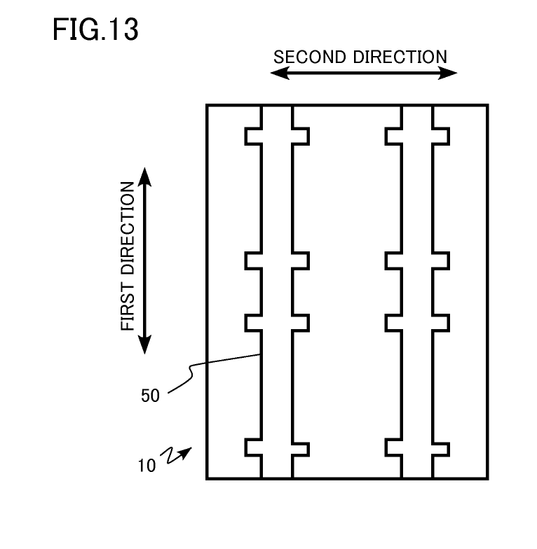

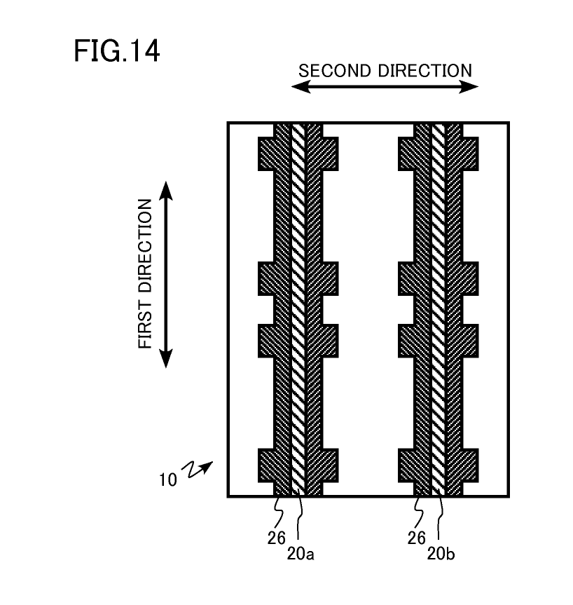

Next, description is given of an exemplary method of manufacturing the semiconductor device according to the third embodiment. FIGS. 13 and 14 are schematic plan views of the semiconductor device in manufacturing processes of the semiconductor device manufacturing method according to the third embodiment.

The method is the same as the manufacturing method described in the first embodiment up to the preparation of a semiconductor substrate 10 with an n⁻-type drift layer 14 and a p-type base layer 16 arranged on an n⁺-type substrate (collector layer) 12.

Next, trenches 50 are formed from the surface of the semiconductor substrate 10 (FIG. 13.) Raised and recessed portions are formed on the side surfaces of the trenches 50 to be later provided with base contact regions 24.

Next, gate insulating films 26 are formed on the inner surfaces of the trenches 50. The gate insulating films 26 are, for example, silicon oxide films. The gate insulating films 26 are, for example, thermal oxide films made by thermal oxidation. The raised and recessed shape of the trenches and conditions for the thermal oxidation are set such that the space between the raised portions on the side surfaces of the trenches 50 is buried with the thermal oxide films when the thermal oxidation is performed.

The gate insulating films 26 may be deposited films formed by CVD in place of thermal oxide films. In case of deposited films, the raised and recessed shape of the trenches and conditions for the deposition are set such that the space between the raised portions on the side surfaces of the trenches 50 is buried with the deposited films.

Moreover, a conductive material is formed over the gate insulating films 26 such that the trenches 50 are buried. The conductive material is, for example, polycrystalline silicon doped with n-type impurities. The surface of the conductive material is polished, for example, by chemical mechanical polishing (CMP) to form gate layers 20a and 20b (FIG. 14.)

After that, emitter regions 22, base contact regions 24, interlayer dielectrics 32, an emitter electrode 28, and a collector electrode 30 are formed by known methods, such that the IGBT depicted in FIG. 12 is completed.

In the IGBT of the third embodiment also, gate capacitance is reduced and deceleration of switching speed is suppressed as in the first embodiment. Further, the IGBT of the third embodiment is fabricated more easily than the device of the first embodiment.

### FOURTH EMBODIMENT

A semiconductor device according to a fourth embodiment is the same as that of the first embodiment except that the semiconductor device further includes a fourth semiconductor layer of the first conductivity type that is disposed between a third gate layer, which is one of the plurality of gate layers, and a first or a second gate layer, so as to be insulated from the emitter electrode. Hence, details overlapping those of the first embodiment are not described redundantly.

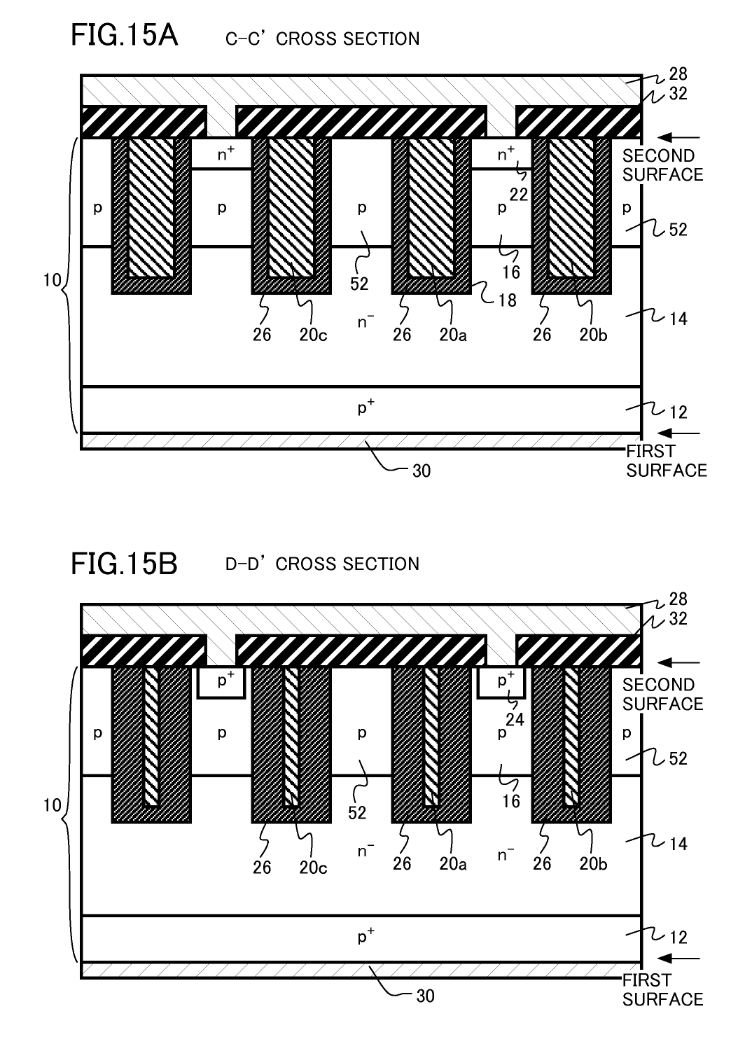

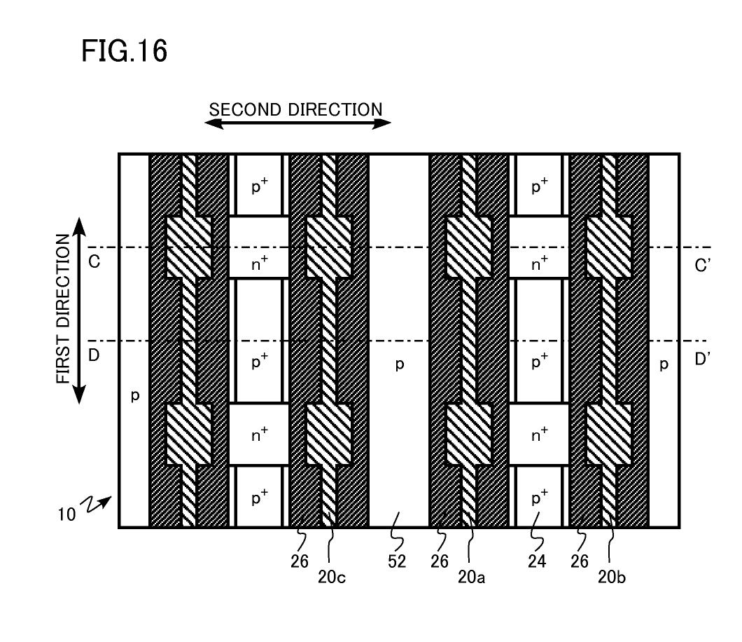

FIGS. 15A and 15B are schematic cross-sectional views of the semiconductor device according to the fourth embodiment. FIG. 16 is a schematic plan view of the semiconductor device according to the fourth embodiment. FIG. 15A depicts a cross section taken along line C-C′ in FIG. 16. FIG. 15B depicts a cross section taken along line D-D′ of FIG. 16. It is to be noted that FIG. 16 is a plan view of a state in which portions such as interlayer dielectrics and an emitter electrode are removed from a semiconductor substrate.

The semiconductor device according to the fourth embodiment is a trench injection enhanced gated transistor (IEGT.) The semiconductor device has an emitter electrode and a collector electrode arranged with a semiconductor substrate interposed therebetween, and includes a dummy region for suppressing discharge of carriers in the on-state.

In the IEGT of the fourth embodiment, a third gate layer 20c is disposed on a side opposite the second gate layer 20b with respect to the first gate layer 20a. A p-type dummy region (fourth semiconductor layer) 52 is provided between the third gate layer 20c and the first gate layer 20a.

The p-type dummy region 52 is electrically insulated from the emitter electrode 28. The p-type dummy region 52 is in a so-called floating state. The dummy region 52 has a function of suppressing discharge of holes and effectively boosting injection of electrons in the on-state of the IEGT.

In the IGBT of the fourth embodiment also, gate capacitance is reduced and deceleration of switching speed is suppressed as in the first embodiment.

In the foregoing embodiments, description is given of examples in which the first conductivity type is p-type and the second conductivity type is n-type; however, the first conductivity type may be n-type, and the second conductivity type may be p-type.

Further, in the foregoing embodiments, description is given of an exemplary material for the semiconductor substrate and semiconductor layers of monocrystalline silicon; however, embodiments of the present invention are applicable to other semiconductor materials, such as silicon carbide and gallium nitride.

While certain embodiments have been described, these embodiments have been presented by way of example only, and are not intended to limit the scope of the inventions. Indeed, semiconductor devices described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device, comprising:
a semiconductor substrate having a first surface and a second surface opposite the first surface;
a first semiconductor layer of a first conductivity type provided in the semiconductor substrate, the first semiconductor layer provided at a first surface side of the semiconductor substrate;
a second semiconductor layer of a second conductivity type provided in the semiconductor substrate, the second semiconductor layer provided between the first semiconductor layer and the second surface;
a third semiconductor layer of the first conductivity type provided in the semiconductor substrate, the third semiconductor layer provided between the second semiconductor layer and the second surface;
a plurality of gate layers provided inside the semiconductor substrate, the gate layers extending in a first direction and being arranged in line in a second direction orthogonal to the first direction, a distance between the gate layers and the first surface is smaller than a distance between the third semiconductor layer and the first surface;
a plurality of first semiconductor regions of the second conductivity type provided in the third semiconductor layer between a first gate layer and a second gate layer of the gate layers, the first and second gate layers being adjacent to each other;
a gate insulating film provided between the first gate layer and each of the second semiconductor layer, the third semiconductor layer, and the first semiconductor regions, a thickness of the gate insulating film between the first gate layer and a region excluding the first semiconductor regions being larger than a thickness of the gate insulating film between the first gate layer and the first semiconductor regions;
an emitter electrode electrically connectable with the first semiconductor regions; and
a collector electrode electrically connectable with the first semiconductor layer.

2. The device according to claim 1, wherein a film thickness of the gate insulating film between the first gate layer and a region sandwiched by the first semiconductor regions adjacent to each other in the first direction is larger than the film thickness of the gate insulating film between the first gate layer and the first semiconductor regions.

3. The device according to claim 1, further comprising a second semiconductor region of the first conductivity type provided between the first semiconductor regions adjacent to each other in the first direction, the second semiconductor region being electrically connectable with the emitter electrode, wherein a film thickness of the gate insulating film between the first gate layer and the second semiconductor region is larger than a film thickness of the gate insulating film between the first gate layer and the first semiconductor regions.

4. The device according to claim 3, wherein a region of a larger film thickness and a region of a smaller film thickness are alternately arranged in the first direction in the gate insulating film between the first gate layer and the second semiconductor region.

5. The device according to claim 1, wherein the film thickness of the gate insulating film between the first gate layer and the second and third semiconductor layers is larger on a first surface side of the second semiconductor than on a first surface side of the first semiconductor regions.

6. The device according to claim 1, further comprising a fourth semiconductor layer of the first conductivity type between a third gate layer and the first gate layer or the second gate layer, the third gate layer being one of the gate layers, the fourth semiconductor layer being insulated from the emitter electrode.

7. The device according to claim 1, wherein the first conductivity type is p-type, and the second conductivity type is n-type.

8. The device according to claim 1, wherein the semiconductor substrate is monocrystalline silicon.

9. The device according to claim 1, wherein the first gate layer and the second gate layer are polycrystalline silicon doped with impurities.

10. The device according to claim 1, wherein the gate insulating film is a silicon oxide film.

11. A semiconductor device, comprising:
a semiconductor substrate having a first surface and a second surface opposite the first surface;
a gate layer provided inside the semiconductor substrate;
a channel region provided in the semiconductor substrate;
a gate insulating film provided between the gate layer and the semiconductor substrate, a thickness of the gate insulating film between the gate layer and a region excluding the channel region being larger than a thickness of the gate insulating film between the gate layer and the channel region;
an emitter electrode provided on a second surface side of the semiconductor substrate; and
a collector electrode provided on a first surface side of the semiconductor substrate.

12. The device according to claim 11, wherein the semiconductor substrate is monocrystalline silicon.

13. The device according to claim 11, wherein the gate layer is polycrystalline silicon doped with impurities.

14. The device according to claim 11, wherein the gate insulating film is a silicon oxide film.
